(19) United States
(12) Patent Application Publication
(10) Pub. No.: US 2008/0213470 A1
(43) Pub. Date: Sep. 4, 2008

(54) Method and Device for Marking Long Objects by Sublimation

(76) Inventor: Bernard Claveau, Martignat (FR)

Correspondence Address: BLANK ROME LLP, 600 NEW HAMPSHIRE AVENUE, N.W., WASHINGTON, DC, 20037, US

(21) Appl. No.: 10/562,317

(22) PCT Filed: Jun. 24, 2004
(86) PCT No.: PCT/FR2004/001597

§ 371 Date: Apr. 2, 2007

(30) Foreign Application Priority Data
Jun. 24, 2003 (FR) 03/07627
Oct. 29, 2003 (FR) 03/12632

(51) Int. Cl. B41M 5/00; C23C 16/00

(52) U.S. Cl. 427/145; 118/722

(57) ABSTRACT

The invention relates to a method for marking objects by sublimation and applying decorated film or paper to bars of profiled elements having polygonal sections and an undefined length by sublimation or by sticking the decorative layer to the bar as it passes through a die and a heated drawing plate supported by a vibrating base plate.

This invention relates to a method of decorating extruded bars made from PVC, wood, aluminium and others, by sublimation on all its contours and lengths simultaneously.

Traditionally, this decoration is carried out on a flat surface and placed under pressure for several minutes, over a very limited length. This flat decoration cannot sublimate all the contours of the extruded object at the same time. For example, in the case of a profile with a square cross-section, it must be presented four times under the press for several minutes, and the connections never match.

The device according to the invention makes it possible to reduce the decoration time over the entire perimeter and can treat pieces with infinite dimensions. In fact, it comprises, according to a first characteristic, a heating matrix, which vibrates, and the core has a cone-shaped intake, ending in the shape of the type of profile to be sublimated, over infinite lengths. The sublimable ink support can be removed manually or automatically at the outlet of the device.

This device according to the invention allows the application of a decorative film and, in this case, no support waste needs to be removed.

The principle according to the invention involves passing through the centre of the matrix, which can be fixed or mobile as required for the type of extruded bar, by means of a rolling effect that enables continuous sublimation.

The principle according to the invention involves turning the object to be marked into the motor. The decoration support is driven because the friction coefficient of the decoration support against the die is lower than the friction coefficient of the decoration support against the object to be decorated. For this reason, the choice of material for the die must take into account the product to be decorated as well as its surface roughness. The choice must also consider temperature requirements in the case of sublimation.

The appended drawings illustrate the invention:

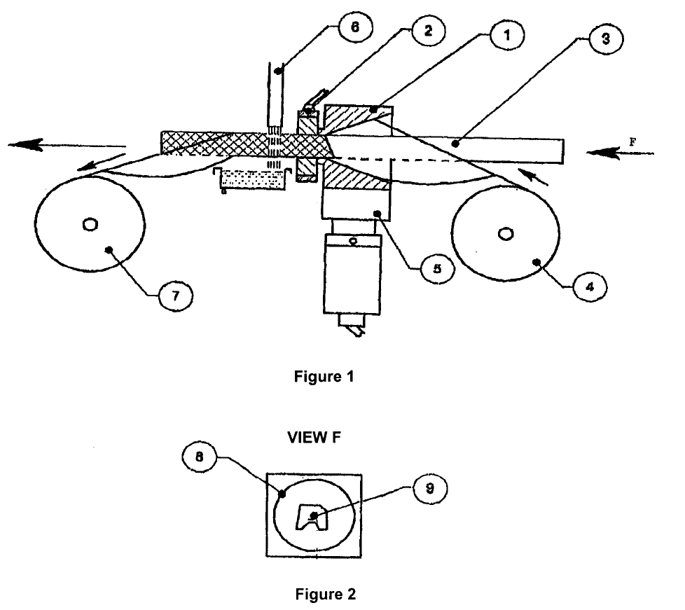

FIG. 1 shows a cross-section of the action of the matrix during the passage of the film or paper with the bar or profile to be sublimated;

FIG. 2 shows the intake and outlet of the matrix.

In reference to these drawings, the device comprises a base plate (5) that vibrates at high frequencies, which supports the entire matrix (1).

The matrix (1) can be made from steel, elastomer or resin.

The extruded bar (3) enters, together with the film or paper (4), in the core of the matrix (1) which shapes the paper or film (4) to pass through the die (2), which is heated to a temperature of around 180° C., in which the effect of the concept makes it possible to sublimate continuously in several seconds, or to glue the film or paper to the extruded bar (3) being decorated.

It is possible to sublimate power cables, tubes, rope, curtain rails made from wood, PVC, metal, profiles for windows, parquet flooring, etc.

The invention therefore relates to:
a method of marking by sublimation and application of decorated film or paper on extruded bars (3) with polygonal cross-sections, with no restrictions on length, by sublimation or decorative veneering through a matrix (1) and a die (2), which are heated and supported by a vibrating base plate (5);
a device for implementing said method, in which:
the inside of the die (2) is in the shape of the object (3) to be decorated.
the extruded bar (3) to be decorated, according to the nature of its material, can be cooled or not at the outlet of the device by spraying (6) with a cooling liquid such as water.
the winding (7) of the waste in the case of sublimation can be automatic or manual.
the base plate (5) that supports the matrix (1) and the die (2) vibrates by means of processes such as the generation of ultrasounds or vibration by electromagnet.
the die (2) can be built into the cone (1) that shapes the decoration support (4).
the die (2) can replace the cone (1) with a simple chamfer at its intake in cases in which the shape of the product to be marked (3) is simple.
the intermediate sections of the cone (1) are obtained by the principle of morphing. The intake (8) has a circular cross-section; the cross-section of the outlet (9) is in the shape of the product to be marked (3).
the cone (1) can act as a die (2) by virtue of its outlet shape, thus doing away with the need for mounting a die (2).
in the case of the product to be marked (3) comprising small irregularities in its shape, O-rings can be mounted in a series of gorges inside the die (2), which ensure that correct contact is maintained between the decoration support (4) and the product to be marked (3).

1. A method of marking by sublimation and application of decorated film or paper on extruded bars with polygonal cross-sections, with no limit on length, the method comprising the step of:
applying decorated film or paper on extruded bars by sublimation or decorative veneering through a matrix and a die, which are heated and supported by a vibrating base plate.

2. A device for implementing the method according to claim 1, wherein an inside of the die is in the shape of the object to be decorated.

3. The device according to claim 2, wherein the device is configured to cool the extruded bar to be decorated, according to the nature of its material, at the outlet of the device by spraying the extruded bar with a cooling liquid.

4. The device according to claim 2, wherein the device is configured to carry out a winding of waste in the case of sublimation automatically.

5. The device according to claim 2, wherein the base plate that supports the matrix and the die vibrates by means of generation of ultrasounds or vibration by an electromagnet.

6. The device according to claim 2, wherein the die can be built into a cone that shapes a decoration support.

7. The device according to claim 6, wherein wherein the device is configured to allow for the die to replace the cone with a simple chamfer at its intake in case in which the shape of the product to be marked is simple.

8. The device according to claim 6, wherein intermediate sections of the cone are obtained through the principle of morphing.

9. The device according to claim 6, wherein the cone can act as a die by virtue of its outlet shape, thus doing away with the need for mounting a die.

10. The device according to claim 2, wherein the device is configured to, in the case of the product to be marked comprises small irregularities in its shape, allow O-rings to be mounted in a series of gorges inside the die, which ensure that correct contact is maintained between the decoration support and the product to be marked.
